(19) United States
(12) Patent Application Publication
(10) Pub. No.: US 2003/0235930 A1
(43) Pub. Date: Dec. 25, 2003

(54) Multi-impression nanofeature production

(75) Inventors: Zhenan Bao, Millburn, NJ (US); Robert W. Filas, Bridgewater, NJ (US)

Correspondence Address: HITT GAINES P.C., P.O. BOX 832570, RICHARDSON, TX, 75083, US

(73) Assignee: Lucent Technologies Inc., Murray Hill, NJ

(21) Appl. No.: 10/179,570

(22) Filed: Jun. 25, 2002

(51) Int. Cl. H01L 21/00

(52) U.S. Cl. 438/21; 101/490

(57) ABSTRACT

A method of producing a nanofeature or a nanocircuit on a substrate, including soaking a stamp having a nanopattern thereon in an ink to allow the ink to absorb into the stamp and provide an inked stamp, and applying the inked stamp against a substrate to transfer an ink pattern onto the substrate, wherein the ink within the inked stamp replenishes the pattern in response to the transfer of the ink pattern.

### TECHNICAL FIELD OF THE INVENTION

The present invention is directed, in general, to nanotechnology and, more specifically, to methods of producing nanofeatures or nanocircuits on a substrate.

### BACKGROUND OF THE INVENTION

Techniques for fabricating and patterning integrated circuits include nanocontact printing to construct gate and source/drain electrodes and appropriate interconnections for functional circuits. Nanocontact printing forms, for example, a patterned self-assembled monolayer (SAM) of “ink” on a uniform layer of metal deposited on a substrate. The SAM may comprise a material resistant to etching, such that subsequent etching of the unprinted regions of the metal layer, followed by removal of the SAM with mild heating, forms electrodes or interconnects. In another conventional nanocontact printing process, the SAM may comprise a catalyst material, the catalyst subsequently being activated to initiate growth of the underlying layer to form electrodes or interconnects. Accordingly, those skilled in the art understand that nanocontact printing may be employed to create a mask resistant to subsequent etching, as well as to create a “seed layer” to be subsequently activated or grown.

One conventional nanocontact printing process employs a stamp comprising polydimethylsiloxane (PDMS) and having an electrode pattern molded or otherwise formed in or on a transfer surface of the stamp. The “ink” may be painted or otherwise deposited on the transfer surface, often including portions of the transfer surface beyond the borders of the pattern to be transferred. Typically, the PDMS stamp is merely dipped into the ink solution for a few seconds to coat the transfer surface with the ink. Conventional “inks” may comprise phosphonic acid, thiol, and/or silane. The stamp provides the means for transferring the ink in a predetermined pattern to the substrate. For instance, the inked surface of the stamp may be brought in contact with the substrate with enough pressure to transfer the ink on the transfer surface onto the substrate.

Conventional nanocontact printing methods exhibit numerous processing disadvantages. For example, the PDMS stamp is dipped into the ink solution only momentarily, such that only a thin layer of ink remains on the transfer surface of the stamp. Once the stamp is brought in contact with the substrate, most of the ink is transferred onto the substrate, such that the ink on the transfer surface is substantially consumed. Even if a substantial portion of the ink on the transfer surface is not transferred to the substrate, the ink remaining on the transfer surface will not form a uniform pattern, because some portions of the transfer pattern will be bare after transferring ink to the substrate. Accordingly, to transfer another instance of the pattern onto the substrate (or another substrate), the pattern on the transfer surface must be re-inked in order to provide a uniform layer of ink on the transfer surface. Such an inconvenience increases the complexity, labor hours and production time of each device being fabricated.

In addition, the material from which the stamp was fabricated also poses a threat to complete transfer of the ink on the pattern on the transfer surface. Specifically, the stamp material typically includes contaminants in the form of residual molecules dissolved in the stamp material. For instance, a stamp comprising PDMS will typically include uncrosslinked siloxane dissolved in the PDMS elastomer. These contaminants can dissolve on or migrate to the transfer surface, such that the contaminants compete with the ink molecules during pattern transfer. When the pattern is transferred to the substrate, the contaminants may be transferred instead of the desired ink molecules. The contaminants will not bind to the substrate as well as the ink, if at all, such that the pattern transferred to the substrate will not be uniform and complete.

Since the contaminants inadvertently transferred to the substrate will not bind well to the metal layer on the substrate, they will dislodge, especially during the subsequent etching process. Accordingly, the substrate portions underlying the contaminants, or the gaps left thereby after the contaminants dislodge, will not be protected during the subsequent etching. The unprotected portions will, therefore, be etched away and prevent uniform formation of the intended metal feature.

The inadvertently transferred contaminants also cause problems in nanocontact printing processes in which the ink transferred is a catalyst to subsequently encourage growth of the underlying metal layer. Specifically, because a complete pattern of catalyst ink is not transferred to the substrate, the subsequent metallization will not occur at the sites of the transferred contaminants. Accordingly, the electrodes or interconnects intended to be grown from the metal layer will not adequately develop, again leaving an electrode pattern that is not uniform or complete.

Accordingly, what is needed in the art is a nanocontact printing process that overcomes the above-described disadvantages of conventional nanocontact printing processes.

### SUMMARY OF THE INVENTION

To address the above-discussed deficiencies of the prior art, the present invention provides a method of producing a nanofeature on a substrate. The method includes soaking a portion of a stamp having a nanopattern thereon in an ink to allow the ink to absorb into the stamp and provide an inked surface. The method also includes applying the inked surface against a substrate to transfer an ink pattern onto the substrate. The ink within the inked stamp replenishes the pattern, in response to the transfer of the ink pattern.

In another embodiment of the present invention, the method of producing a nanofeature on a substrate includes extracting contaminants from the stamp.

The foregoing has outlined preferred and alternative features of the present invention so that those skilled in the art may better understand the detailed description of the invention that follows. Additional features of the invention will be described hereinafter that form the subject of the claims of the invention. Those skilled in the art should appreciate that they can readily use the disclosed conception and specific embodiment as a basis for designing or modifying other structures for carrying out the same purposes of the present invention. Those skilled in the art should also realize that such equivalent constructions do not depart from the spirit and scope of the invention.

### BRIEF DESCRIPTION OF THE DRAWINGS

The invention is best understood from the following detailed description when read with the accompanying FIGUREs. It is emphasized that, in accordance with the standard practice in the industry, various features are not drawn to scale. In fact, the dimensions of the various features may be increased or reduced for clarity of discussion. Reference is now made to the following descriptions taken in conjunction with the accompanying drawings, in which:

FIG. 1 illustrates a three-dimensional view of a stamp that may be employed in one embodiment of a method of producing a nanofeature on a substrate according to the principles of the present invention;

FIG. 2 illustrates a three-dimensional view of the stamp shown in FIG. 3 being soaked according to the principles of the present invention;

FIG. 3 illustrates a side view of the inked stamp shown in FIG. 2 as the stamp is brought in contact with a substrate;

FIG. 4 illustrates a plan view of the substrate shown in FIG. 3 after the inked stamp has been brought in contact with the substrate and removed;

FIG. 5 illustrates a side view of the inked stamp shown in FIG. 3 during another pattern transfer process;

FIG. 6 illustrates a plan view of the substrate shown in FIG. 5 after the inked stamp has been brought in contact with the substrate and removed a second time;

FIG. 7 illustrates a side view of the inked stamp shown in FIG. 5 during another pattern transfer process;

FIG. 8 illustrates a plan view of the substrate shown in FIG. 7 after the inked stamp has been brought in contact with the substrate and removed a number of times;

FIG. 9 illustrates a side view of the substrate shown in FIG. 8 during an electrode formation step according to the principles of the present invention; and

FIGS. 10 and 11 illustrate respective plan and side views of the substrate shown in FIG. 9 after an etching or metallization process is performed according to the principles of the present invention.

### DETAILED DESCRIPTION

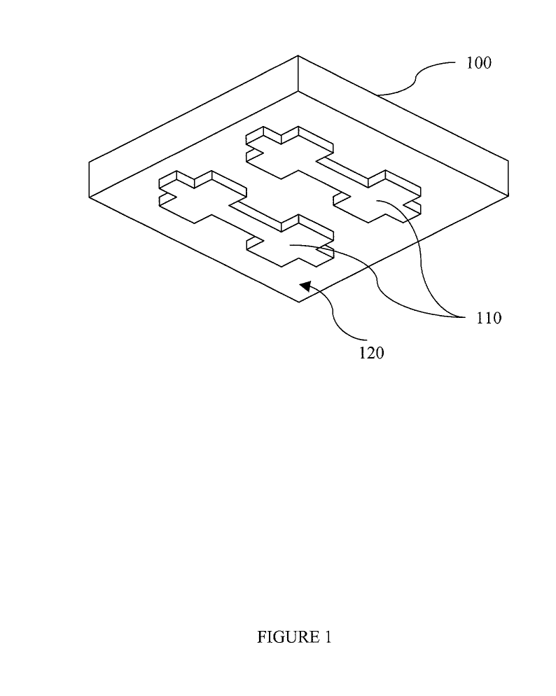

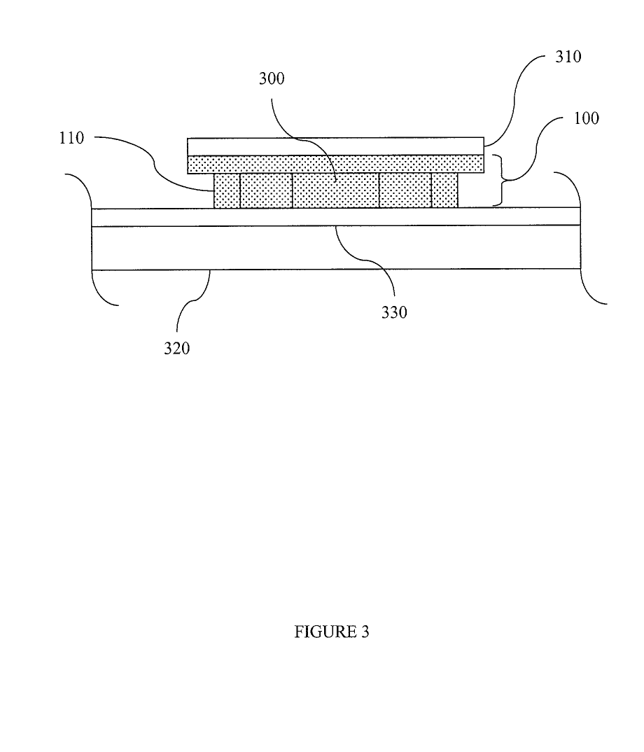

Referring initially to FIG. 1, illustrated is a three-dimensional view of a stamp 100 that may be employed in one embodiment of a method of producing a nanofeature on a substrate (see FIGS. 3-11) according to the principles of the present invention. The stamp 100 may include a transfer pattern 110. The transfer pattern 100 may be a nanopattern of the electrode or circuit pattern to be formed on the substrate, and may represent nanofeatures, which are raised and/or depressed features having lateral dimensions along the surface of less than about 20 microns. The transfer pattern 110 may represent only a portion of a circuit to be formed on the substrate, or may represent the entire circuit. The stamp 100 may be manufactured by conventional methods. The stamp 100 may include a material 200 that comprises a poly(dimethylsiloxane), a copolymer of dimethyl-siloxane, a copolymer of diphenylsiloxane, or a polymer having a glass transition temperature less than about 10 degrees Celsius.

In an advantageous embodiment, the stamp is made of Sylgard 184, a product of Dow Chemical, Corp., in Michigan, U.S. Sylgard 184 comprises two materials: a cross-linkable silicone polymer and a curing agent. The two materials are mixed together to form a viscous liquid that is poured over a mold (not shown) and heated to about 70-90 Celsius for about 3 hours. At this temperature, the silicone polymer will cross-link and solidify into an elastomer, such that the cured stamp 100 may then be peeled away from the mold.

The stamp 100 may have formed thereon patterns other than that shown in FIG. 1, including patterns formed in a transfer surface 120 rather than on the transfer surface 120. In addition, the stamp 100 may be formed by other processes and/or with other materials than those just described. However, in advantageous embodiments, the stamp 100 may comprise materials in which capillary action causes significant absorption of ink, e.g., the ink to be used in transferring the nanopattern with the stamp 100. For instance, the stamp 100 may comprise materials having solubility parameters and diffusion coefficients compatible to those of the ink.

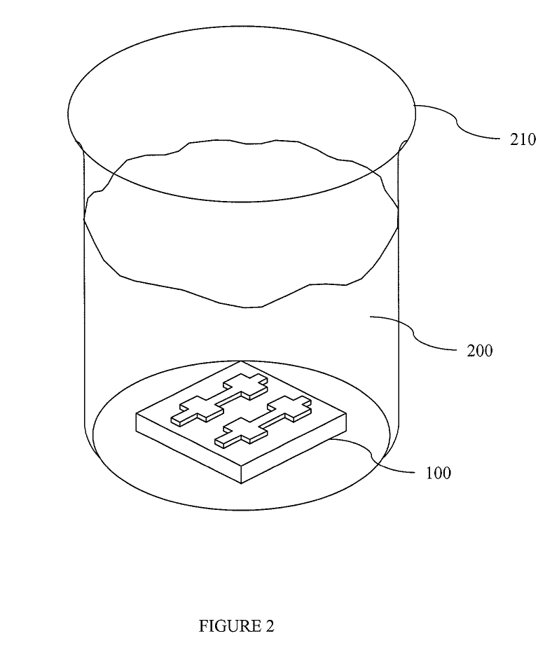

Turning to FIG. 2, illustrated is the stamp 100 shown in FIG. 1, wherein the stamp 100 is being soaked in ink according to the principles of the present invention. In the illustrated embodiment, the stamp 100 is completely immersed in a liquid solution 200 within a container 210. In other embodiments, however, the stamp 100 may be only partially immersed in the liquid solution 200.

During the soaking, the stamp 100 may remain in contact with the liquid ink solution 200 for a significantly longer period than in the processes of the prior art. For example, the stamp 100 may remain in contact with the liquid solution for a period ranging from about 5 minutes to about 10 hours. However, other soaking periods are within the scope of the present invention.

The liquid solution 200 may comprise solution that includes a mixture of surface reactive inks and solvents. For example, the ink solution may comprise thiol, phosphonic acid, silane, or mixtures thereof. Of course, the ink may comprise other materials that are capable of leaving a print on a substrate. By soaking the stamp 100 in the liquid solution 200 comprising the ink solution, the ink diffuses into the material of the stamp 100, effectively creating an ink reservoir within the stamp 100. Accordingly, the stamp 100 absorbs more ink than is required for a single pattern transfer. The additional ink absorbed in the stamp 100 replenishes the surface of the transfer pattern 110 with ink after each pattern transfer. By replenishing the surface of the transfer pattern 110, it is intended that the ink absorbed into the interior of the stamp 100 diffuse or otherwise migrate to the surface of the transfer pattern 110 after each pattern transfer. As discussed below, the stamp 100 may therefore transfer ink patterns two or more times before re-inking, thereby increasing manufacturing efficiency.

In an advantageous embodiment, the stamp 100 may undergo an extraction or cleaning step prior to soaking the stamp 100 in the liquid solution 200. The extraction step removes low molecular weight components which might cause contamination of the ink on the transfer pattern 110. However, an exemplary extraction step includes soaking the stamp 100 in a solvent comprising hexane, thiol, acetone or methylenechloride. The soaking may be for a period ranging between about 5 minutes and about 10 hours, although longer periods are within the scope of the present application. In an advantageous embodiment, the extraction solution comprises solvents having solubility parameters and diffusion coefficients compatible to those of the stamp 100. After soaking, the stamp 100 may be dried in an ambient environment, or at an elevated temperature in a vacuum oven.

In performing the above-described extraction process, the stamp 100 may swell in volume as much as 100 percent or more. During this swelling, the contaminants within the matrix of the material of the stamp 100 may chemically bond with the molecules of the soaking solution, or simply diffuse into the soaking solution. Once the stamp 100 is removed from the soaking solution and allowed to dry, the swelling subsides, and more contaminants within the stamp 100 may diffuse to the surface of the stamp 100, which may then be washed or wiped clean. Alternatively, a continuous extraction may be performed in a Soxhlet extractor. In this manner, contaminants, such as uncrosslinked siloxane polymer, silicon, or residual cyclics from the synthesis of the silicone polymer, are partially or completely removed from the stamp 100 prior to its inking. In an advantageous embodiment, the extracting decreases the concentration of contaminants within the stamp 100 to less than about 1% by weight. The extraction process may be performed in a manner similar to the ink soaking process shown in FIG. 2.

Turning to FIG. 3, illustrated is a side view of the inked stamp 100 after being soaked as discussed above. In the embodiment shown, the interstitial spaces within the matrix of the material of the stamp 100 are substantially saturated with ink 300 from the liquid solution 200, such that the soaked material of the stamp functions as an ink reservoir. In other embodiments, a block 310 integrally forms a single unit with the transfer pattern 110. The block 310 may be comprised of the same material. In such embodiments, the block 310 and the transfer pattern 110 both serve as the ink reservoir.

In the embodiment shown, the inked surface of the stamp 100 can be brought in contact with a substrate 320, such that the transfer pattern 110 makes substantially complete contact with the substrate 320. In an advantageous embodiment, the substrate 320 may include a metal layer 330 against which the inked stamp 100 is pressed. The metal layer 330 may comprise gold, copper, silver, palladium and/or nickel.

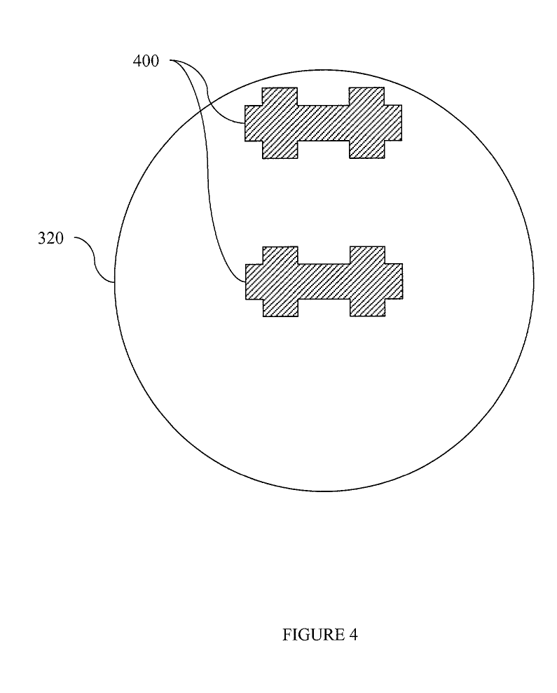

Turning to FIG. 4, illustrated is a plan view of the substrate 320 shown in FIG. 3 after the inked stamp 100 has been brought in contact with the substrate 320 and removed. The transfer pattern 110 of the stamp 100 has transferred to the substrate 320 an ink pattern 400 corresponding to the shape of the transfer pattern 110. In one embodiment, the ink pattern 400 may correspond to a nanopattern of gate electrodes, interconnects or other nanofeatures to be formed on the substrate 320. In an advantageous embodiment, the ink pattern 400 may correspond to features of a partial or complete nanocircuit to be formed on the substrate 320.

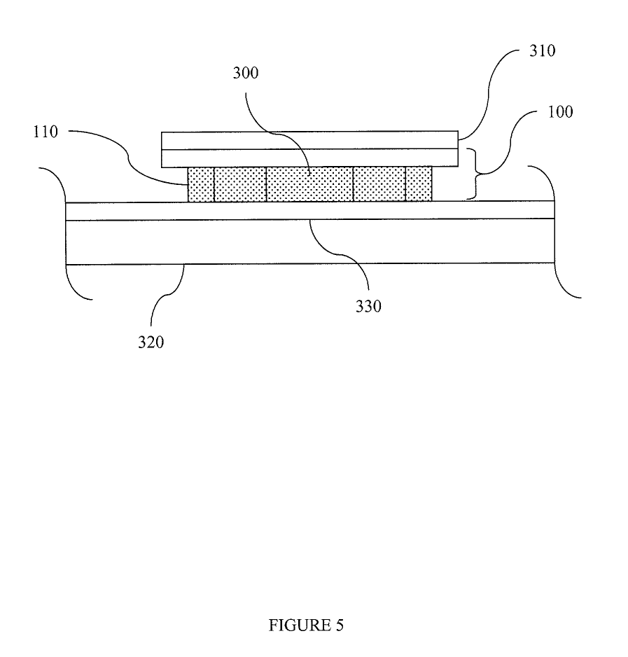

Turning to FIG. 5, illustrated is a side view of the inked stamp 100 after the transfer process described above with reference to FIGS. 3 and 4. The ink reservoir has replenished the transfer pattern 110 with additional ink 300, such that the reservoir contains less ink 300 than it did prior to the transfer. Since the reservoir has replenished the transfer pattern 110, a second pattern transfer may be performed without re-inking the stamp 100. Accordingly, the stamp 100 may be brought in contact with or pressed against the substrate 320 again, as described above.

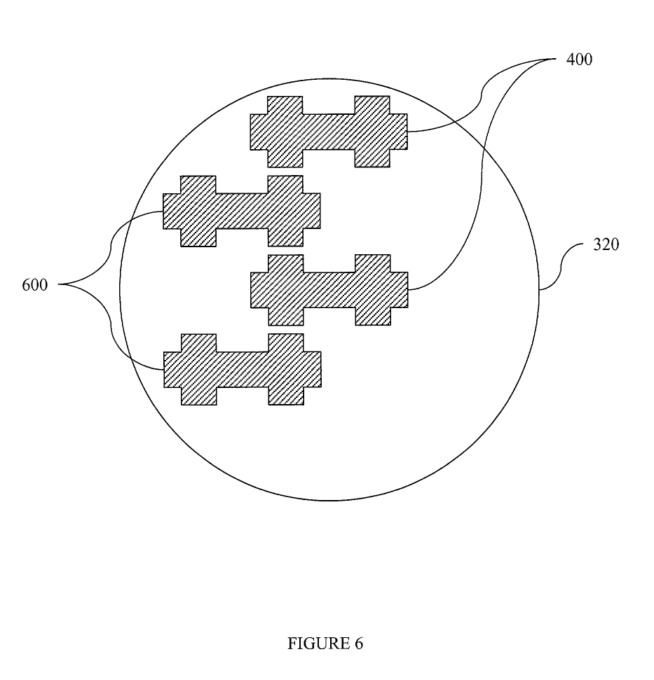

Turning to FIG. 6, illustrated is a plan view of the substrate 320 shown in FIG. 5 after the inked stamp 100 has been brought in contact with or pressed against the substrate 320 and removed a second time. The transfer pattern 110 has transferred to the substrate 320 a second ink pattern 600 corresponding to the shape of the transfer pattern 110. The second ink pattern 600 is substantially similar or identical to the first ink pattern 400.

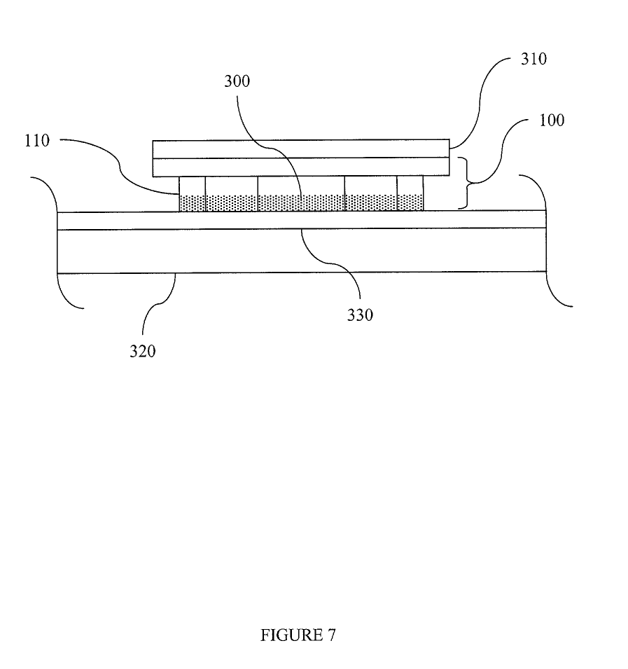

Turning to FIG. 7, illustrated is a side view of the inked stamp 100 after the transfer process described above. The reservoir has again replenished the transfer pattern 110 with additional ink 300 a second time, such that the reservoir contains less ink 300 than it did prior to the second transfer process. Since the reservoir has replenished the transfer pattern 110, additional pattern transfers may be performed without re-inking the stamp 100.

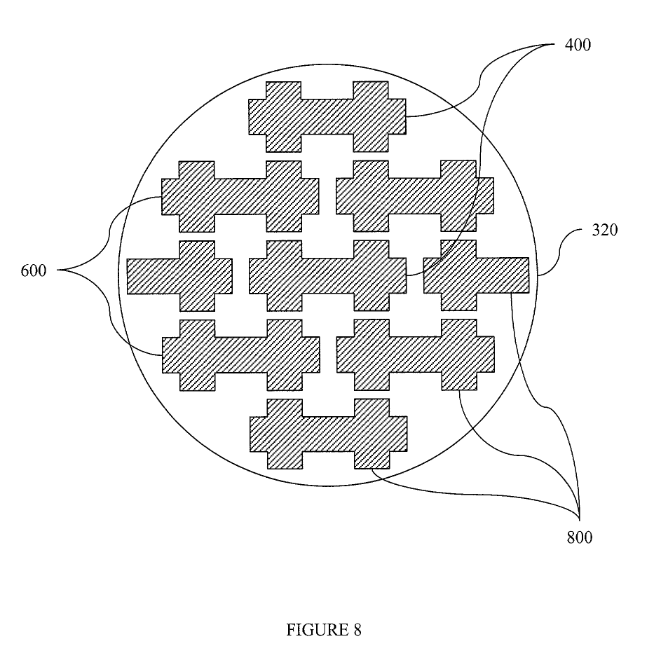

Turning to FIG. 8, illustrated is a plan view of the substrate 320 after the inked stamp 100 has been brought in contact with or pressed against the substrate 320 and removed a number of times. The transfer pattern 110 of the inked stamp 100 has transferred to the substrate 320 a plurality of ink patterns 800 corresponding to the shape of the transfer pattern 110. The ink patterns 800 are identical to the ink pattern 400.

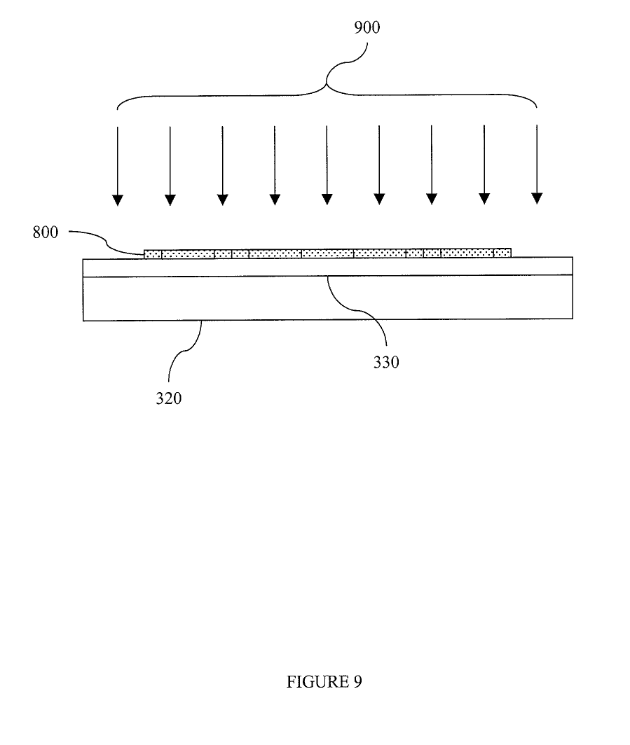

Turning to FIG. 9, illustrated is a side view of the substrate 320 shown in FIG. 8 during an electrode formation step according to the principles of the present invention. In the embodiment shown, the substrate 320 may be subjected to etching, such as wet etching, as indicated by the arrows 900. The ink patterns 800 protect underlying portions of the substrate 320 or the metal layer 330 from the effects of the etching process. In such instances, the ink patterns 800 mask or protect portions of the substrate 320, such that the etching removes unprotected portions of the substrate 320 to thereby substantially duplicate the transfer pattern 110 onto the substrate 320 or metal layer 330, as the case may be.

However, in other embodiments, the substrate 320 may be subjected to a metallization process, such as electroless plating, wherein metallization may be catalyzed or otherwise initiated on the portions of the substrate 320 or metal layer 330 underlying the ink patterns 800. In such embodiments, the ink patterns 800 may comprise a catalyst or a complexing agent for a metal ion, which can bind a metal ion and become a catalyst for electroless metallization. For instance, the ink patterns 800 may comprise one or more materials from amino groups or other nitrogen containing functional groups. The ink therein may then bind to palladium catalysts in the substrate 320, metal layer 330 or ink patterns 800, and initialize plating of nickel, gold, palladium or other metals at areas corresponding to the ink patterns 800. Accordingly, the ink patterns 800 may be seed layers, and the ink transferred by the transfer pattern 110 may include a catalyst, a metal or both. In alternative embodiments, the metallization process may include anodizing. Those having skill in the art understand how such etching and metallization processes may be accomplished.

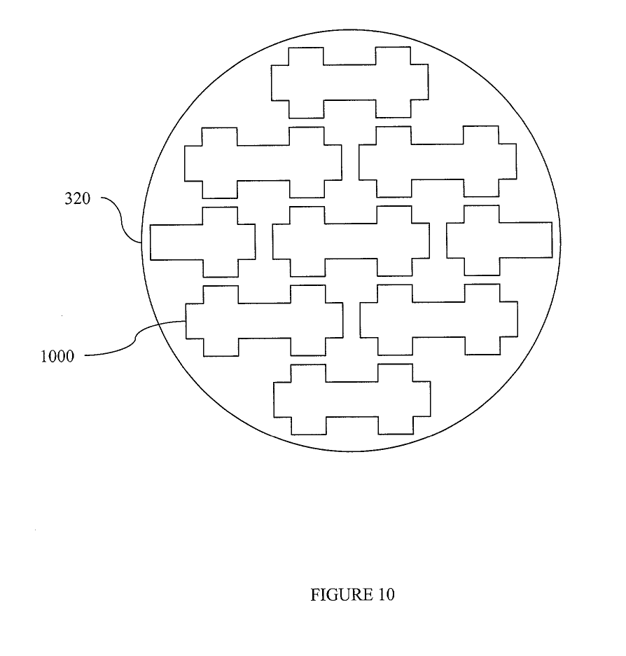

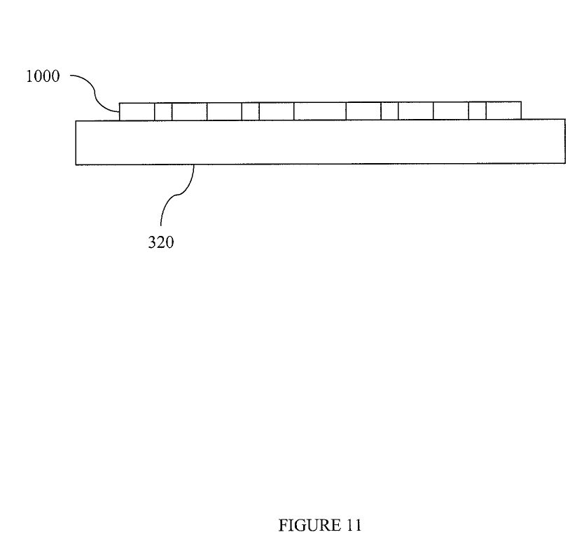

Turning to FIGS. 10 and 11, illustrated are respective plan and side views of the substrate 320 after the etching or metallization process is performed as described with reference to FIG. 9. As a result of the etching or metallization process, nanofeatures 1000 are formed on the substrate 320 in a pattern corresponding to multiple instances of the transfer pattern 110 (see FIG. 3). The nanofeatures 1000 may comprise gate electrodes, interconnects and/or other features, including those of a thin-film transistor. In an advantageous embodiment, the nanofeatures 1000 may form a partial or complete pattern for a nanocircuit. The nanofeatures 1000 may comprise metallic or semiconductor material, depending on the materials selected for the ink, the substrate 320 and the metal layer 330.

The present invention thus provides a process for transferring several instances of electrode or interconnect nanopatterns or nanocircuits to substrates without requiring the re-inking of the transfer medium between each transfer, because the transfer medium may absorb the transfer ink. In addition, the present invention also provides a process for transferring a more uniform pattern free of contaminants, because the transfer medium may be soaked in a decontamination solution or extracted prior to soaking the medium in the transfer ink.

Although the present invention has been described in detail, those skilled in the art should understand that they can make various changes, substitutions and alterations herein without departing from the spirit and scope of the invention in its broadest form.

What is claimed is:

1. A method of producing a nanofeature on a substrate, comprising:
soaking a portion of a stamp having a nanopattern thereon in an ink to absorb said ink into said stamp and produce an inked surface on said nanopattern; and
applying said inked surface against a substrate to transfer an ink pattern onto said substrate, said ink within said inked stamp replenishing said surface of said nanopattern.

2. The method as recited in claim 1 wherein said soaking includes placing at least a portion of said stamp in said ink.

3. The method as recited in claim 1 wherein said nanopattern includes features having lateral dimensions of less than about 20 microns.

4. The method as recited in claim 1 wherein said applying includes transferring said ink pattern onto said substrate at least two times before re-inking said stamp.

5. The method as recited in claim 1 wherein said stamp comprises a material selected from the group consisting of:
poly(dimethylsiloxane);
copolymers of dimethylsiloxane; and
copolymers of diphenylsiloxane.

6. The method as recited in claim 1 wherein said stamp comprises a polymer having a glass transition temperature less than about 10 degrees Celsius.

7. The method as recited in claim 1 wherein said ink comprises a compound selected from the group consisting of:
thiol;
phosphonic acid; and
silane.

8. The method as recited in claim 1 wherein said ink and said stamp have solubility parameters and diffusion coefficients such that said ink absorbs into said stamp during said soaking.

9. The method as recited in claim 1 further comprising extracting contaminants from said stamp prior to performing said soaking.

10. The method as recited in claim 9 wherein said extracting includes extracting by continuous solvent extraction in a Soxhlet extractor or soaking said stamp in a solvent.

11. A method of producing a nanocircuit on a substrate, comprising:
soaking a stamp having a nanopattern thereon in an ink to absorb said ink into said stamp and produce an inked surface on said nanopattern;
applying said inked surface against a substrate to create a transferred ink pattern on said substrate, said ink within said inked stamp replenishing said surface in response to said creation of said transferred ink pattern; and
forming at least a portion of a nanocircuit with said transferred ink pattern.

12. The method as recited in claim 11 wherein said transferred nanopattern is a mask that protects portions of said substrate and said forming includes removing portions of said substrate that are unprotected by said mask.

13. The method as recited in claim 12 wherein said removing includes etching said substrate.

14. The method as recited in claim 11 wherein said transferred ink pattern is a seed layer and said forming includes forming said at least a portion of said nanocircuit with an electroless process.

15. The method as recited in claim 14 wherein said ink includes a catalyst or a complexing agent for bonding ions of a metal to said substrate.

16. The method as recited in claim 15 wherein said metal is selected from the group consisting of:
gold;
copper;
silver;
palladium; and
nickel.

17. The method as recited in claim 11 wherein said ink pattern includes features of a thin-film transistor.

18. The method as recited in claim 10 further comprising extracting contaminants from said stamp.

19. The method as recited in claim 18 wherein said extracting includes decreasing a contaminant concentration in at least portions of said stamp adjacent said nanopattern surface to less than about 1% by weight.

20. A method of decontaminating a stamp having a nanopattern thereon, comprising:
extracting contaminants from at least a portion of a matrix of a stamp having a nanopattern thereon by soaking at least a portion of said stamp in a solvent.
